(19) United States
(12) Patent Application Publication
(10) Pub. No.: US 2022/0019881 A1
(43) Pub. Date: Jan. 20, 2022

(54) MEMORY FOR PERFORMING DEEP NEURAL NETWORK OPERATION AND OPERATING METHOD THEREOF

(71) Applicant: Winbond Electronics Corp., Taichung City (TW)

(72) Inventors: Tay-Jyi Lin, Taichung City (TW); Yi-Hsuan Ting, Taichung City (TW); Hao-Hsuan Shen, Taichung City (TW)

(73) Assignee: Winbond Electronics Corp., Taichung City (TW)

(21) Appl. No.: 17/373,725

(22) Filed: Jul. 12, 2021

(30) Foreign Application Priority Data
Jul. 17, 2020 (TW) 109124237

(51) Int. Cl. G06N 3/063; G06N 3/04; G06F 11/07

(52) U.S. Cl. CPC G06N 3/063; G06F 11/0775; G06N 3/0445

(57) ABSTRACT

A memory is suitable for performing a deep neural network operation. The memory includes: a processing unit and a weight unit. The processing unit includes a data input terminal and a data output terminal. The weight unit is configured to be coupled to the data input terminal of the processing unit. The weight unit includes an index memory and a mapping table. The index memory is configured to store multiple weight indexes. The mapping table is configured to respectively map the multiple weight indexes to multiple representative weight data.

### CROSS REFERENCE TO RELATED APPLICATION

This application claims the priority benefit of Taiwan application serial no. 109124237, filed on Jul. 17, 2020. The entirety of the above-mentioned patent application is hereby incorporated by reference herein and made a part of this specification.

### BACKGROUND

### 1. Technical Field

The disclosure relates to a memory for performing a deep neural network operation and an operating method thereof.

### 2. Description of Related Art

With the evolution of artificial intelligence (AI) operations, AI operations are more and more widely used. For example, neural network operations such as image analysis, speech analysis, and natural language processing are performed using neural network models. Therefore, AI research and development as well as application continues in various technical fields, and numerous algorithms suitable for Deep Neural Networks (DNN), Convolutional Neural Networks (CNN) and the like are also constantly being introduced.

However, no matter which algorithm is used in neural network operations, the amount of data used in the hidden layer to achieve machine learning is very large. Specifically, the operation of deep neural networks is actually based on the matrix operation between neurons and weights. In such case, it takes a lot of memory space to store the weights when deep neural network operations are performed. If stuck-at-faults occur in the memory storing the weights, the operation of the deep neural network will be wrong. Therefore, how to provide a memory and the operating method thereof that can reduce the stuck-at-faults and improve the accuracy of deep neural network operations is an important topic.

### SUMMARY

The disclosure provides a memory and an operating method thereof for performing a deep neural network operation capable of finding a coded data with the least stuck-at-faults to represent a mapping relationship between a weight index and a representative weight data, thereby reducing the stuck-at-faults in an index memory.

The disclosure provides a memory suitable for performing a deep neural network operation. The memory includes: a processing unit and a weight unit. The processing unit includes a data input terminal and a data output terminal. The weight unit is configured to be coupled to the data input terminal of the processing unit. The weight unit includes an index memory and a mapping table. The index memory is configured to store multiple weight indexes. The mapping table is configured to respectively map the multiple weight indexes to multiple representative weight data.

The disclosure provides a memory operating method suitable for performing a deep neural network operation. The memory operating method includes a mapping method. The mapping method includes: coupling a weight unit to a data input terminal of a processing unit, where the weight unit includes an index memory storing multiple weight indexes and a mapping table respectively mapping the multiple weight indexes to multiple representative weight data; detecting the index memory to generate a fault map, where the fault map includes multiple stuck-at-faults; counting the number of stuck-at-faults of a coded data between each of the representative weight data and the corresponding weight index according to the fault map; and selecting sequentially the coded data with the least stuck-at-faults to create the mapping table between the multiple representative weight data and the multiple weight indexes.

In summary, in the embodiment of the disclosure, multiple weight values are grouped into the multiple representative weight data, and the multiple weight indexes are respectively mapped to the multiple representative weight data through the mapping table, so as to greatly reduce the memory space for storing the multiple weight values. In addition, in the embodiment of the disclosure, the above-mentioned mapping table is created by detecting the index memory to generate the fault map, counting the number of stuck-at-faults of the coded data between each of the representative weight data and the corresponding weight index according to the fault map, and selecting sequentially the coded data with the least stuck-at-faults. In this way, the embodiment of the disclosure may effectively reduce the stuck-at-faults of the index memory, thereby improving the accuracy of the deep neural network operation.

### BRIEF DESCRIPTION OF THE DRAWINGS

FIG. 1 is a schematic diagram of a memory according to an embodiment of the disclosure.

FIG. 2 is a diagram showing the relationship between an index memory and a mapping table according to an embodiment of the disclosure.

FIG. 3 is a mapping table according to an embodiment of the disclosure.

FIG. 4 is a flowchart of a memory operating method according to an embodiment of the disclosure.

FIG. 5 is a fault map according to an embodiment of the disclosure.

FIG. 6A to FIG. 6C are flowcharts of step 404 of FIG. 4.

FIG. 7 is a table showing the relationship between a representative weight data and a coded data according to an embodiment of the disclosure.

### DESCRIPTION OF THE EMBODIMENTS

In order to make the content of the disclosure more comprehensible, the following embodiments are specifically cited as examples on which the disclosure can be implemented. In addition, wherever possible, elements/components/steps with the same reference numerals in the drawings and embodiments represent the same or similar components.

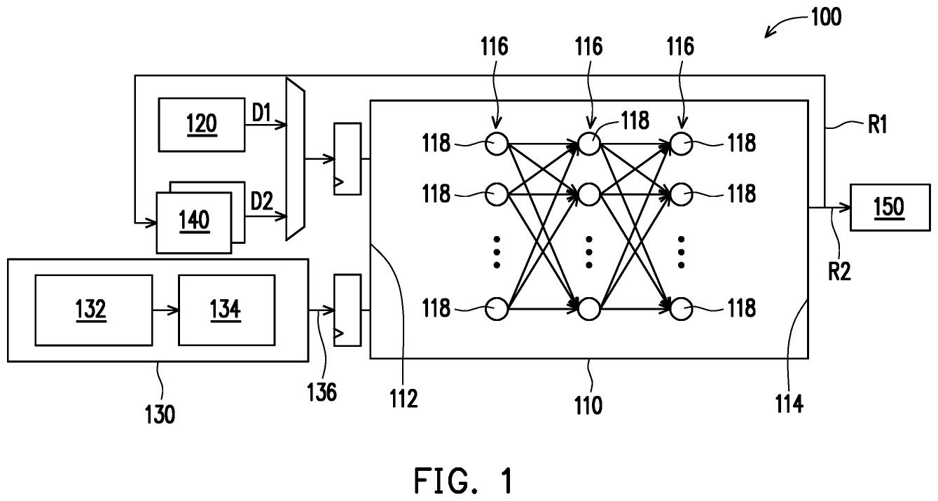

Referring to FIG. 1, the embodiment of the disclosure provides a memory 100 including a processing unit 110, a data input unit 120, a weight unit 130, a feedback unit 140, and a data output unit 150. Specifically, the processing unit 110 includes a data input terminal 112 and a data output terminal 114. In some embodiments, the processing unit 110 may be an artificial intelligence engine, for example, a Processing In Memory (PIM) architecture or a Near Memory Processing (NMP) architecture constructed by circuit elements such as control logic, arithmetic logic, cache memory, and the like. In the present embodiment, the processing unit 110 is designed to perform deep neural network operations. In such case, the memory 100 of the present embodiment may be a dynamic random access memory (DRAM) chip, a resistive random access memory (RRAM), a phase-change random access memory (PCRAM), a magnetoresistive random-access memory (MRAM), or the like, but the disclosure is not limited thereto.

In some embodiments, the data input unit 120 and the weight unit 130 are configured to be respectively coupled to the data input terminal 112 of the processing unit 110, and the feedback unit 140 is configured to be coupled to the data input terminal 112 and the data output terminal 114 of the processing unit 110. For example, when the processing unit 110 performs a deep neural network operation, the processing unit 110 may access an operation input data (or operation input value) D1 in the data input unit 120 and a weight data 136 in the weight unit 130, and perform the deep neural network operation according to the input data D1 and the weight data 136. In the present embodiment, the processing unit 110 may be regarded as a hidden layer in the deep neural network that is formed by multiple layers 116 interconnected back and forth, where each of the layer 116 includes multiple neurons 118. When the input data D1 and the weight data 136 are processed through the processing unit 110 and an operation result value R1 is obtained, the operation result value R1 will be re-input to the processing unit 110 through the feedback unit 140 as a new operation input data (or operation input value) D2, so as to complete an operation of the hidden layer. All hidden layers are operated in the same way until completion, and a final operation result value R2 of an output layer is sent to the data output unit 150.

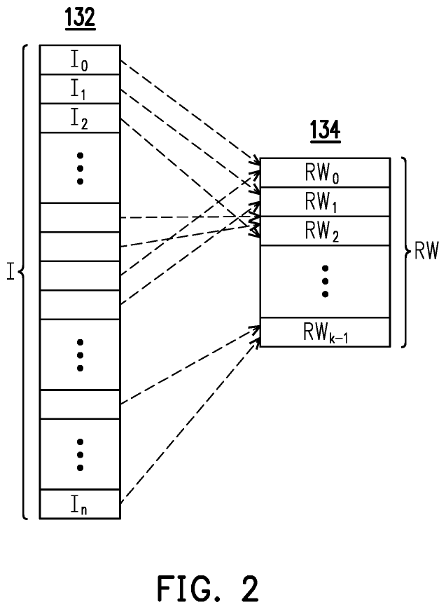

It is worth noting that in the prior art, a weight data is usually expressed as a floating point and stored in a weight memory. In such case, it takes a lot of memory space to store the weight data when deep neural network operations are performed. Accordingly, in the embodiment of the disclosure, the conventional weight memory is replaced by the weight unit 130, so as to reduce the storage space of the memory. Specifically, the weight unit 130 includes an index memory 132 and a mapping table 134. As shown in FIG. 2, the index memory 132 is configured to store multiple weight indexes I₀, I₁, I₂ . . . Iₙ (hereinafter collectively referred to as a weight index I). The number of the weight index I is equivalent to the number of the conventional weight data and is related to the number of interconnected layers in the hidden layer and the number of neurons in each layer, and the above-mentioned should be familiar to those with ordinary knowledge in the neural network field and will not be described in detail here. In addition, the mapping table 134 is configured to respectively map the multiple weight indexes I to multiple representative weight data RW₀, RW₁, RW₂ . . . RWₖ₋₁ (hereinafter collectively referred to as a representative weight data RW). In some embodiments, multiple weight values (for example, the conventional weight data) may be grouped into the representative weight data RW, thereby reducing the number of the representative weight data RW. In such case, a weight change of the representative weight data RW may be smaller than a weight change of the weight value so as to reduce an error rate of the deep neural network operation. In addition, the number of the weight index I may be more than the number of the representative weight data RW. As shown in FIG. 2, one or more weight indexes I may correspond to the same representative weight data RW at the same time.

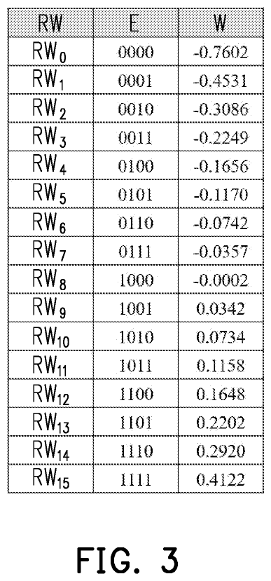

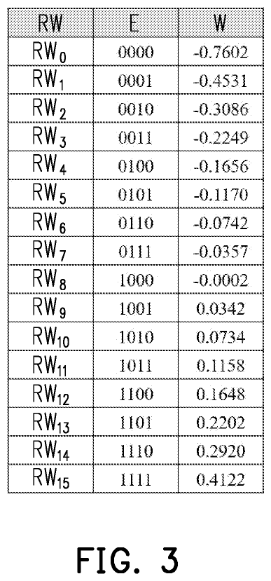

In some embodiments, as shown in FIG. 3, the mapping table 134 includes multiple coded data E to represent the mapping relationship between the multiple weight indexes I and the multiple representative weight data RW. For example, as shown in FIG. 2 and FIG. 3, the I₀ in the weight index I may correspond to the representative weight value W “−0.7602” in the representative weight data RW₀ through the “0000” in the encoded data E. However, when a stuck-at-fault occurs in the index memory 132 storing the weight index I, the operation of deep neural network will still be wrong. In such case, the following embodiment provides a mapping method capable of finding the coded data E with the least stuck-at-faults to represent the mapping relationship between the weight index I and the representative weight data RW, thereby reducing the stuck-at-faults in the index memory 132.

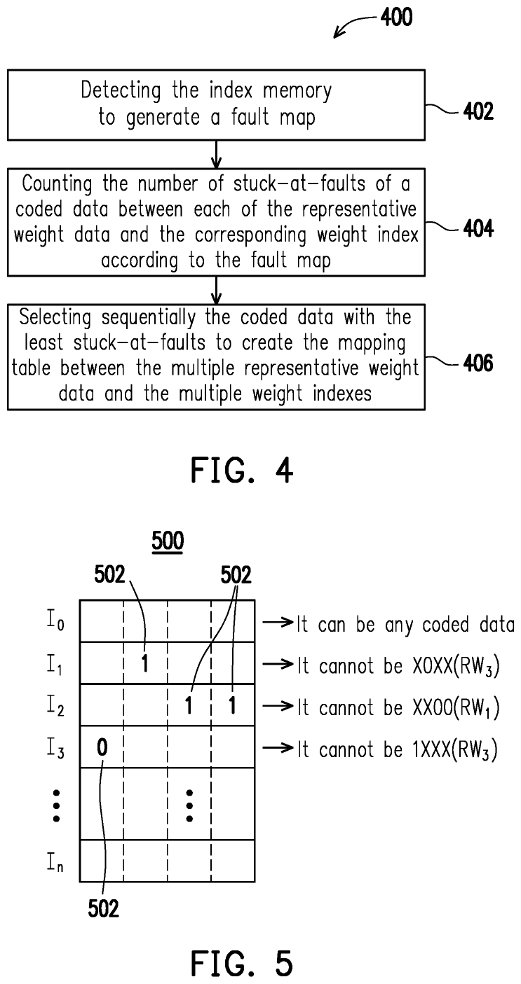

Referring to FIG. 4, the embodiment of the disclosure provides a memory operating method 400 suitable for performing a deep neural network operation. The memory operating method 400 includes a mapping method as shown below. First, step 402 is performed to generate a fault map 500 by detecting the index memory, as shown in FIG. 5. In some embodiments, the fault map 500 includes multiple stuck-at-faults 502. Here, the so-called stuck-at-fault means that a state level of a memory cell is always 0 or always 1. For example, as shown in FIG. 5, the state level of each memory cell storing the weight index I may be represented by four bits. Each bit position is a power of two. The state level of the memory cell storing the weight index I₁ may be “X1XX”; in other words, the second bit position of this memory cell is always 1, and the other bit positions may be 1 or 0 (represented by X). In such case, if a coded data of “X0XX” is used to correspond to the weight index I₁, a stuck-at-fault will occur. Similarly, a state level of the memory cell storing the weight index I₂ may be “XX11”; and a state level of the memory cell storing the weight index I₃ may be “0XXX”. In addition, a state level of the memory cell storing the weight index I₀ may be “XXXX”; in other words, any coded data may be used to correspond to the weight index I₀. It should be understood that the aforementioned memory cell may also have two bits to represent four state levels, or more bits to represent more state levels.

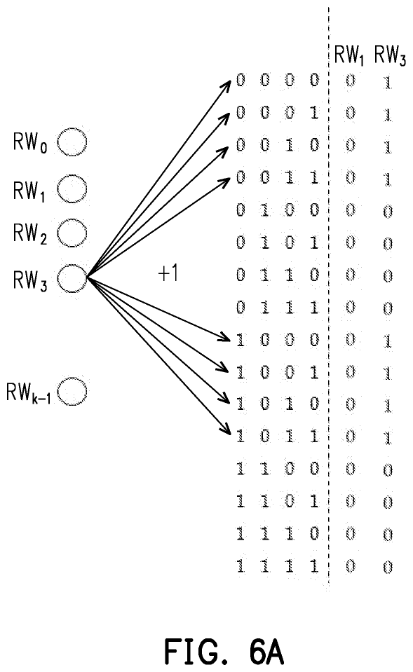

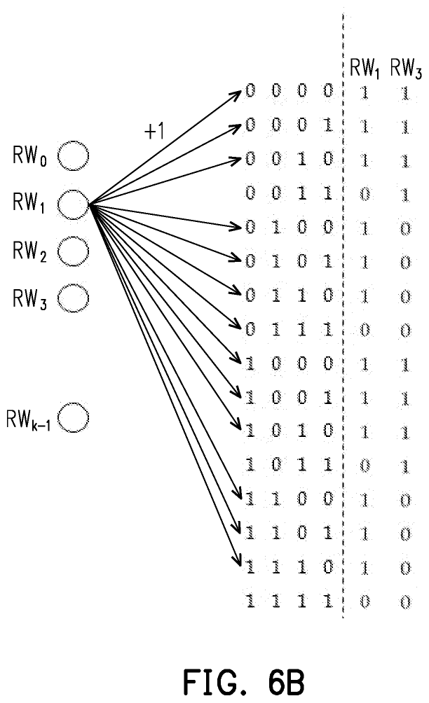

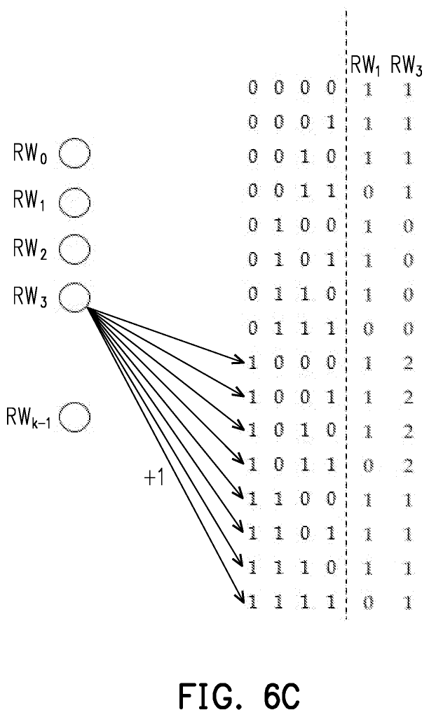

Next, step 404 is performed to count the number of stuck-at-faults of the coded data between each of the representative weight data and the corresponding weight index according to the fault map. For example, as shown in FIG. 5, when the weight index I₁ corresponds to the representative weight data RW₃, the state level of the memory cell storing the weight index I₁ is “X1XX”. In other words, the stuck-at-fault will occur in the coded data with “X0XX”, as represented by a symbol of +1 shown in FIG. 6A. Similarly, as shown in FIG. 5, when the weight index I₂ corresponds to the representative weight data RW₁, the state level of the memory cell storing the weight index I₂ is “XX11”. In other words, the stuck-at-fault will occur in the coded data with “XX00”, as represented by a symbol of +1 shown in FIG. 6B. Next, as shown in FIG. 5, when the weight index I₃ corresponds to the representative weight data RW₃, the state level of the memory cell storing the weight index I₃ is “0XXX”. In other words, the stuck-at-fault will occur in the coded data with “1XXX”, as represented by a symbol of +1 shown in FIG. 6C. Each stuck-at-fault of the coded data E between each of the representative weight data RW and the corresponding weight index I is counted in the same way until completion.

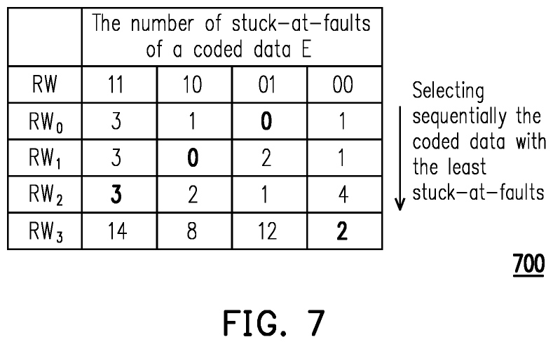

Then, step 406 is performed to create a mapping table between the multiple representative weight data and the multiple weight indexes by selecting sequentially the coded data with the least stuck-at-faults. FIG. 7 illustrates a table 700 showing the relationship between the representative weight data and the coded data E. Although in the above embodiment, the coded data is represented by four bits to represent the sixteen state levels, for ease of explanation, the four status levels are represented by two bits in FIG. 7.

In detail, when the representative weight data RW is arranged in the order of the representative weight data RW₀, RW₁, RW₂, and RW₃, the corresponding coded data E may be selected in this order. For example, as shown in FIG. 7, since in the row of the representative weight data RW₀, the coded data “01” has the least stuck-at-faults (that is, 0), the coded data “01” in the multiple coded data E may be selected to correspond to the representative weight data RW₀. In other words, the number of the stuck-at-faults of the coded data “01” is less than the number of the stuck-at-faults of other coded data “11”, “10”, and “00”. Then, in the row of the representative weight data RW₁, the coded data “10” has the least stuck-at-faults (that is, 0), the coded data “10” in the multiple coded data E may be selected to correspond to the representative weight data RW₁. It is worth noting that although in the row of the representative weight data RW₂, the coded data “01” or “10” has less stuck-at-faults (that is, 1 or 2), but since the coded data “01” or “10” has been selected to correspond to the representative weight data RW₀ or RW₁, the coded data “11” in the multiple coded data E may then be selected to correspond to the representative weight data RW₂. In other words, each of the weight data RW may correspond to a different coded data E. Finally, in the row of the representative weight data RW₃, the coded data “00” has the least stuck-at-faults (that is, 2), therefore the coded data “00” in the multiple coded data E may be selected to correspond to the representative weight data RW₃. After performing step 402, step 404, and step 406 of the above operating method of the memory 400, the coded data E with the least stuck-at-faults may be found to represent the mapping relationship between the weight index I and the representative weight data RW, so as to effectively reduce the stuck-at-faults of the index memory 132 (as shown in FIG. 1) and further improve the accuracy of the deep neural network operation.

In some embodiments, when the deep neural network operation is performed, as shown in FIG. 1, the required weight index may be read from the index memory 132 and the corresponding representative weight data (or the representative weight value) may be mapped through the above-mentioned mapping table. Then, the corresponding representative weight data may be input into the processing unit 110 to perform the deep neural network operation.

In summary, in the embodiment of the disclosure, the multiple weight values are grouped into the multiple representative weight data, and the multiple weight indexes are respectively mapped to the multiple representative weight data through the mapping table, so as to greatly reduce the memory space for storing the multiple weight values. In addition, in the embodiment of the disclosure, the above-mentioned mapping table is created by detecting the index memory to generate the fault map, counting the number of stuck-at-faults of the coded data between each of the representative weight data and the corresponding weight index according to the fault map, and selecting sequentially the coded data with the least stuck-at-faults. In this way, the embodiment of the disclosure may effectively reduce the stuck-at-faults of the index memory, thereby improving the accuracy of deep neural network operation.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A memory suitable for performing a deep neural network operation, the memory comprising:
a processing unit comprising a data input terminal and a data output terminal; and
a weight unit configured to be coupled to the data input terminal of the processing unit, wherein the weight unit comprises:
an index memory configured to store a plurality of weight indexes; and
a mapping table configured to respectively map the plurality of weight indexes to a plurality of representative weight data.

2. The memory according to claim 1, wherein the mapping table comprises a plurality of coded data to represent a mapping relationship between the plurality of weight indexes and the plurality of representative weight data.

3. The memory according to claim 1, wherein the mapping table is created by detecting the index memory to generate a fault map, counting the number of stuck-at-faults of the coded data between each of the representative weight data and the corresponding weight index according to the fault map, and selecting sequentially the coded data with the least stuck-at-faults.

4. The memory according to claim 1, wherein the plurality of representative weight data are obtained by grouping a plurality of weight values.

5. The memory according to claim 4, wherein a weight change of the plurality of representative weight data is smaller than a weight change of the plurality of weight values.

6. The memory according to claim 1, further comprising:
a data input unit configured to be coupled to the data input terminal of the processing unit and configured to input an operation input value to the processing unit.

7. The memory according to claim 1, further comprising:
a feedback unit configured to be coupled to the data input terminal and the data output terminal, wherein the feedback unit re-inputs an operation result value output by the processing unit to the processing unit as a new operation input value.

8. A memory operating method suitable for performing a deep neural network operation, the memory operating method comprising a mapping method, the mapping method comprising:
coupling a weight unit to a data input terminal of a processing unit, wherein the weight unit comprises an index memory storing a plurality of weight indexes and a mapping table respectively mapping the plurality of weight indexes to a plurality of representative weight data;
detecting the index memory to generate a fault map, wherein the fault map comprises a plurality of stuck-at-faults;
counting the number of the stuck-at-faults of a coded data between each of the representative weight data and the corresponding weight index according to the fault map; and
selecting sequentially the coded data with the least stuck-at-faults to create the mapping table between the plurality of representative weight data and the plurality of weight indexes.

9. The memory operating method according to claim 8, wherein the step of selecting sequentially the coded data with the least stuck-at-faults comprises:
selecting a first coded data in the plurality of coded data to correspond to a first representative weight data of the plurality of representative weight data.

10. The memory operating method according to claim 9, wherein the number of stuck-at-faults using the first coded data to correspond to the first representative weight data is less than the number of stuck-at-faults using other coded data in the plurality of coded data to correspond to the first representative weight data.

11. The memory operating method according to claim 9, further comprising:
selecting a second coded data in the plurality of coded data to correspond to a second representative weight data in the plurality of representative weight data,
selecting a third coded data in the plurality of coded data to correspond to a third representative weight data in the plurality of representative weight data,
selecting a fourth coded data in the plurality of coded data to correspond to a fourth representative weight data in the plurality of representative weight data, wherein the first coded data, the second coded data, the third coded data, and the fourth coded data comprise different coded data.

12. The memory operating method according to claim 8, further comprising a reading method, wherein the reading method comprises:
reading the required weight index from the index memory and mapping a corresponding representative weight data through the mapping table.

13. The memory operating method according to claim 12, wherein the reading method comprises:
inputting the corresponding representative weight data to the processing unit to perform the deep neural network operation.

14. The memory operating method according to claim 8, wherein the mapping method further comprises: grouping a plurality of weight values into the plurality of representative weight data.

15. The memory operating method according to claim 14, wherein a weight change of the plurality of representative weight data is smaller than a weight change of the plurality of weight values.
